(19) United States
(12) Patent Application Publication
(10) Pub. No.: US 2017/0089952 A1
(43) Pub. Date: Mar. 30, 2017

(54) Load Providing Test and Diagnostic Assist Device

(71) Applicant: Jesse Davis, Virginia Beach, VA (US)

(72) Inventor: Jesse Davis, Virginia Beach, VA (US)

(21) Appl. No.: 14/865,668

(22) Filed: Sep. 25, 2015

(51) Int. Cl. G01R 1/14; H01R 25/00; G01R 31/02; H01H 71/10

(52) U.S. Cl. CPC G01R 1/14; H01H 71/1045; H01R 25/006; G01R 31/02

(57) ABSTRACT

A load providing test and diagnostic assist device for provision of power to equipment undergoing diagnostic testing and repair includes a breaker that is sized appropriately to the amperage of the equipment under repair. The device includes a power cable and a power cord that are gauged appropriately to the current source supplied to the equipment under repair. The power cable has a first terminus and a second terminus. The power cord has a first end and a second end. The first end and the first terminus are electrically coupled to the breaker. A connector is electrically coupled to the second terminus of the power cable. The connector is couplable to an alternating current source. A coupler is electrically coupled to the second end of the power cord.

### BACKGROUND OF THE DISCLOSURE

### Field of the Disclosure

The disclosure relates to load providing devices and more particularly pertains to a new load providing device for provision of power to equipment undergoing diagnostic testing and repair.

### SUMMARY OF THE DISCLOSURE

An embodiment of the disclosure meets the needs presented above by generally comprising a breaker that is sized appropriately to the amperage of the equipment under repair. The device includes a power cable and a power cord that are gauged appropriately to the current source supplied to the equipment under repair. The power cable has a first terminus and a second terminus. The power cord has a first end and a second end. The first end and the first terminus are electrically coupled to the breaker. A connector is electrically coupled to the second terminus of the power cable. The connector is couplable to an alternating current source. A coupler is electrically coupled to the second end of the power cord.

There has thus been outlined, rather broadly, the more important features of the disclosure in order that the detailed description thereof that follows may be better understood, and in order that the present contribution to the art may be better appreciated.

There are additional features of the disclosure that will be described hereinafter and which will form the subject matter of the claims appended hereto.

The objects of the disclosure, along with the various features of novelty which characterize the disclosure, are pointed out with particularity in the claims annexed to and forming a part of this disclosure.

### BRIEF DESCRIPTION OF THE DRAWINGS

The disclosure will be better understood and objects other than those set forth above will become apparent when consideration is given to the following detailed description thereof. Such description makes reference to the annexed drawings wherein:

FIG. 1 is a front isometric view of a load providing test and diagnostic assist device according to an embodiment of the disclosure.

FIG. 2 is an exploded view of an embodiment of the disclosure.

FIG. 3 is a bottom cut-away view of an embodiment of the disclosure.

FIG. 4 is a side view of an embodiment of the disclosure.

FIG. 5 is a block diagram of an embodiment of the disclosure.

### DESCRIPTION OF THE PREFERRED EMBODIMENT

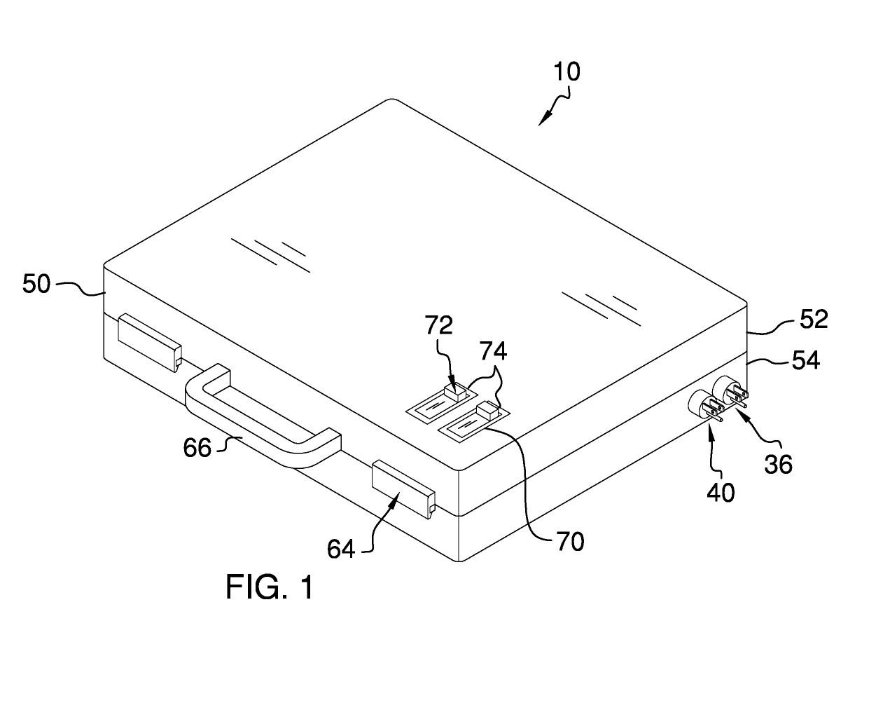

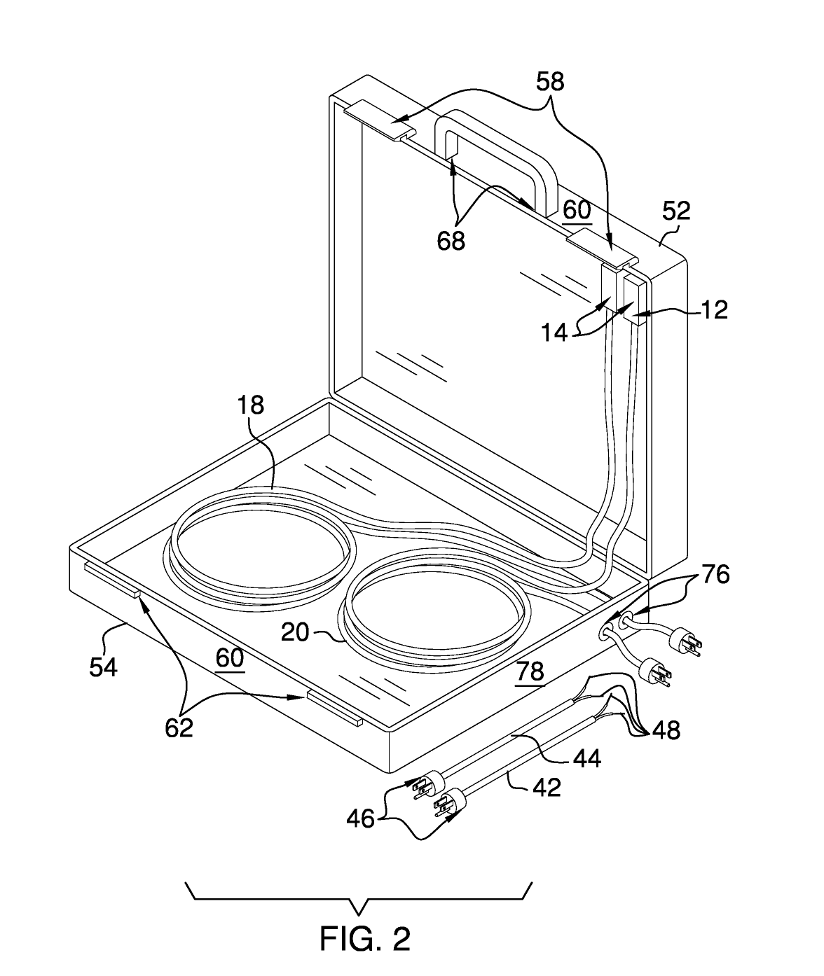

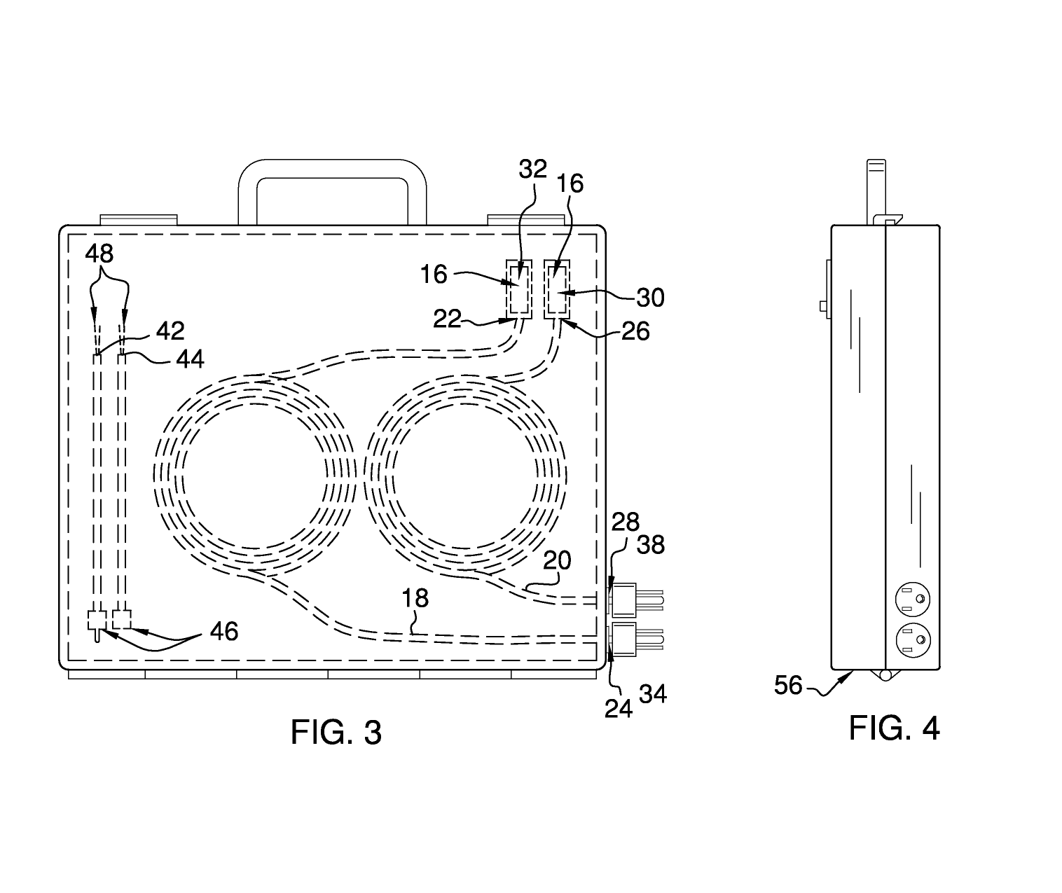

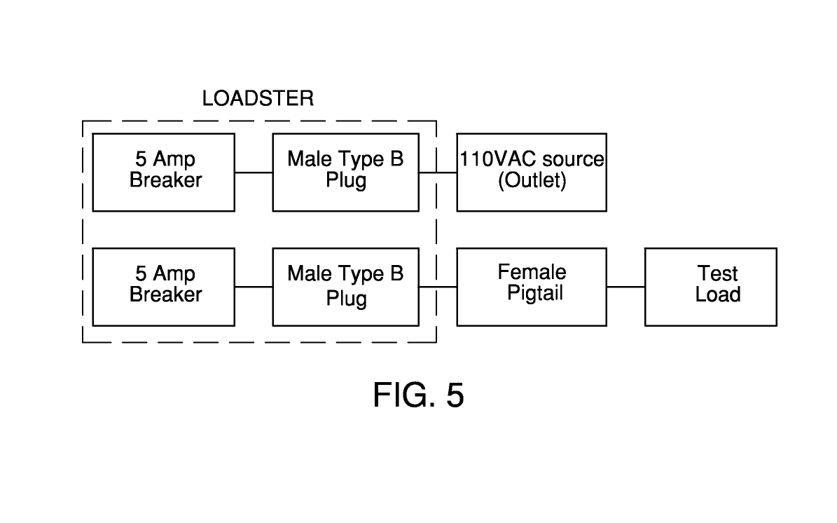

With reference now to the drawings, and in particular to FIGS. 1 through 5 thereof, a new load providing device embodying the principles and concepts of an embodiment of the disclosure and generally designated by the reference numeral 10 will be described.

As best illustrated in FIGS. 1 through 5, the load providing test and diagnostic assist device 10 generally comprises a breaker 12 that is sized appropriately to the amperage of the equipment under repair. The breaker 12 is single poled and may comprise a pair of breakers 14 that are electronically coupled. The breaker 12 may comprise a 5 Amp breaker 16.

The device 10 includes a power cable 18 and a power cord 20 that are gauged appropriately to the current source supplied to the equipment under repair. The power cable 18 has a first terminus 22 and a second terminus 24. The power cord 20 has a first end 26 and a second end 28. The first end 26 and the first terminus 22 are electrically coupled to the breaker 12. The first end 26 of the power cord 20 is electrically coupled to a first one 30 of the pair of breakers 14. The first terminus 22 of the power cable 18 is electrically coupled to a second one 32 of the pair of breakers 14. The power cable 18 and the power cord 20 are gauged to 100-127 volts. The power cable 18 is between 5 and 200 feet in length. The power cable 18 may be between 10 and 150 feet in length. Preferably, the power cable 18 is between 15 and 100 feet in length. The power cord 20 is between 5 and 50 feet in length. The power cord 20 may be between 10 and 40 feet in length. Preferably, the power cord 20 is between 15 and 30 feet in length. A connector 34 is electrically coupled to the second terminus 24 of the power cable 18. The connector 34 is couplable to an alternating current source. The connector 34 is selected from the group of plug types consisting of plug Types A, B, C, D, E, F, G, H, I, J, K, L, M, N, and 0. Preferably, the connector 34 comprises a first Type B plug 36. A coupler 38 is electrically coupled to the second end 28 of the power cord 20. The coupler 38 is selected from the group of plug and socket types consisting of plug and socket Types A, B, C, D, E, F, G, H, I, J, K, L, M, N, and 0. Preferably, the coupler comprises a second Type B plug 40.

The device 10 comprises a male pigtail 42 and a female pigtail 44 each having a coupling end 46 and a pair of wire contacts 48. The coupling ends 46 are complimentary to the coupler 38, such that the coupler 38 is configured to connect to the coupling end 46 of the male pigtail 42 and the coupling end 46 of the female pigtail 44 with the wire contacts 48 positioned to connect to the power supply wires of the equipment under repair.

The device 10 also comprises clamshell case 50 comprising a top piece 52 and a bottom piece 54 hingedly joined along a back 56 of the case 50. The top piece 52 has a plurality of first fasteners 58 coupled to a front 60 of the case 50. The plurality of first fasteners 58 may comprise two first fasteners. The bottom piece 54 has a plurality of second fasteners 62 coupled to the front 60. The second fasteners 62 are complimentary to the first fasteners 58. The plurality of second fasteners 62 may comprise two second fasteners. Preferably, the first fasteners 58 and the second fasteners 62 comprise a clasp-type closure 64. The case 50 has a handle 66 with opposing ends 68 coupled to the front 60. The opposing ends 68 are coupled to the top piece 52. Preferably the handle 66 is hingedly coupled to the top piece 52, such that the handle 66 is positionable both perpendicular to the front 60 and parallel to the front 60. A slot 70 is positioned in the top piece 52 proximate to the front 60. The slot 70 is complimentary to a switch 72 positioned on the breaker 12. The slot 70 comprises a pair of slots 74. A pair of holes 76 is positioned in a side 78 of the case 50 proximate to the back 56, preferably in the bottom piece 54. The breaker 12 is coupled to the top piece 52 such that the switch 72 is positioned in the slot 70 and accessible to the user with the case 50 in a closed configuration. The power cord 20 is positioned in the case 50 with the second end 28 extending through a respective one of the pair of holes 76. The power cable 18 is positioned in the case 50 with the second terminus 24 extending through a respective one of the pair of holes 76.

In use, the power cable 18 and the power cord 20 are positioned in the case 50 with the coupler 38 and the connector 34 positioned outside of the case 50 and extendable away from the case 50 when the user withdraws the power cable 18 and the power cord 20 through the pair of holes 76. The coupler 38 is configured to engage a respective coupling end 46 of the male pigtail 42 or the female pigtail 44 with the pair of wire contacts 48 configured to electronically couple to the equipment undergoing repair, such that supplying power to the equipment during diagnostic testing and repair can be performed in a safe and convenient manner.

With respect to the above description then, it is to be realized that the optimum dimensional relationships for the parts of an embodiment enabled by the disclosure, to include variations in size, materials, shape, form, function and manner of operation, assembly and use, are deemed readily apparent and obvious to one skilled in the art, and all equivalent relationships to those illustrated in the drawings and described in the specification are intended to be encompassed by an embodiment of the disclosure.

Therefore, the foregoing is considered as illustrative only of the principles of the disclosure. Further, since numerous modifications and changes will readily occur to those skilled in the art, it is not desired to limit the disclosure to the exact construction and operation shown and described, and accordingly, all suitable modifications and equivalents may be resorted to, falling within the scope of the disclosure. In this patent document, the word “comprising” is used in its non-limiting sense to mean that items following the word are included, but items not specifically mentioned are not excluded. A reference to an element by the indefinite article “a” does not exclude the possibility that more than one of the element is present, unless the context clearly requires that there be only one of the elements.

I claim:

1. A load providing test and diagnostic assist device comprising:
a breaker, said breaker being sized appropriately for the amperage of the equipment under repair;
a power cable and a power cord, said power cable and said power cord being gauged appropriately for the current source supplied to the equipment under repair, said power cable having a first terminus and a second terminus, said power cord having a first end and a second end, said first end and said first terminus being electrically coupled to said breaker;
a connector, said connector being electrically coupled to said second terminus of said power cable, said connector being couplable to an alternating current source; and
a coupler, said coupler being electrically coupled to said second end of said power cord.

2. The device of claim 1, further including said breaker being single poled.

3. The device of claim 1, further including said breaker comprising a pair of breakers.

4. The device of claim 3, further including said pair of breakers being electronically coupled.

5. The device of claim 1, further including said breaker comprising a 5 Amp breaker.

6. The device of claim 3, further comprising:
said first end of said power cord being electrically coupled to a first one of said pair of breakers; and
said first terminus of said power cable being electrically coupled to a second one of said pair of breakers.

7. The device of claim 1, further including said connector being selected from the group of plug types consisting of plug Types A, B, C, D, E, F, G, H, I, J, K, L, M, N, and O.

8. The device of claim 7, further including said connector comprising a first Type B plug.

9. The device of claim 1, further including said coupler being selected from the group of plug and socket types consisting of plug and socket Types A, B, C, D, E, F, G, H, I, J, K, L, M, N, and O.

10. The device of claim 9, further including said coupler comprising a second Type B plug.

11. The device of claim 1, further including a male pigtail and a female pigtail, said pigtails having a coupling end and a pair of wire contacts, said coupling ends being complimentary to said coupler, wherein said coupler is configured to connect to said coupling end of said male pigtail and said coupling end of said female pigtail with said wire contacts being positioned to connect to the power supply wires of the equipment under repair.

12. The device of claim 1, further including a clamshell case comprising:
a top piece and a bottom piece hingedly joined along a back of said case;
a handle coupled to said front, said handle having opposing ends, said opposing ends being coupled to said top piece;
a slot positioned in said top piece proximate to said front, said slot being complimentary to a switch positioned on said breaker;
said power cord being positioned in said case, and
said power cable being positioned in said case.

13. The device of claim 12, further comprising:
said top piece having a plurality of first fasteners coupled to a front of said case; and
said bottom piece having a plurality of second fasteners coupled to said front, said second fasteners being complimentary to said first fasteners.

14. The device of claim 13, further comprising:
said plurality of first fasteners comprising two first fasteners; and
said plurality of second fasteners comprising two second fasteners.

15. The device of claim 15, further including said first fasteners and said second fasteners comprising a clasp-type closure.

16. The device of claim 12, further including said opposing ends being hingedly coupled to said top piece, such that said handle is positionable both perpendicular to said front and parallel to said front.

17. The device of claim 12, further including said breaker being coupled to said top piece such that said switch is positioned in said slot and accessible to the user with said case in a closed configuration.

18. The device of claim 12, further including a pair of holes positioned in a side of said case proximate to said back, said pair of holes being positioned in said bottom piece.

19. The device of claim 18, further comprising:
said power cord being positioned in said case with said second end extending through a respective one of said pair of holes; and
said power cable being positioned in said case with said second terminus extending through a respective one of said pair of holes, such that said coupler and said connector are positioned outside of said case and extendable away from said case when the user withdraws said power cable and said power cord through said pair of holes.

20. A load providing test and diagnostic assist device comprising:
a breaker, said breaker being sized appropriately for the amperage of the equipment under repair, said breaker being single poled, said breaker comprising a pair of breakers, said pair of breakers being electronically coupled, said breaker comprising a 5 Amp breaker;
a power cable and a power cord, said power cable and said power cord being gauged appropriately for the current source supplied to the equipment under repair, said power cable having a first terminus and a second terminus, said power cord having a first end and a second end, said first end and said first terminus being electrically coupled to said breaker, said first end of said power cord being electrically coupled to a first one of said pair of breakers, said first terminus of said power cable being electrically coupled to a second one of said pair of breakers, said power cable and said power cord being gauged for 100-127 volts, said power cable being between 5 and 200 feet in length, said power cable being between 10 and 150 feet in length, said power cable being between 15 and 100 feet in length; said power cord being between 5 and 50 feet in length, said power cord being between 10 and 40 feet in length, said power cord being between 15 and 30 feet in length;
a connector, said connector being electrically coupled to said second terminus of said power cable, said connector being couplable to an alternating current source, said connector being selected from the group of plug types consisting of plug Types A, B, C, D, E, F, G, H, I, J, K, L, M, N, and O;
said connector comprising a first Type B plug;
a coupler, said coupler being electrically coupled to said second end of said power cord, said coupler being selected from the group of plug and socket types consisting plug and socket Types A, B, C, D, E, F, G, H, I, J, K, L, M, N, and O; said coupler comprising a second Type B plug;
a male pigtail and a female pigtail, said pigtails having a coupling end and a pair of wire contacts, said coupling ends being complimentary to said coupler, wherein said coupler is configured to connect to said coupling end of said male pigtail and said coupling end of said female pigtail with said wire contacts being positioned to connect to the power supply wires of the equipment under repair;
a clamshell case, said case comprising:
a top piece and a bottom piece hingedly joined along a back of said case,
said top piece having a plurality of first fasteners coupled to a front of said case, said plurality of first fasteners comprising two first fasteners,
said bottom piece having a plurality of second fasteners coupled to said front, said second fasteners being complimentary to said first fasteners, said plurality of second fasteners comprising two second fasteners, said first fasteners and said second fasteners comprising a clasp-type closure,
a handle coupled to said front, said handle having opposing ends, said opposing ends being coupled to said top piece, said opposing ends being hingedly coupled to said top piece, such that said handle is positionable both perpendicular to said front and parallel to said front,
a slot positioned in said top piece proximate to said front, said slot being complimentary to a switch positioned on said breaker, said slot comprising a pair of slots, and
a pair of holes positioned in a side of said case proximate to said back, said pair of holes being positioned in said bottom piece;
said breaker being coupled to said top piece such that said switch is positioned in said slot and accessible to the user with said case in a closed configuration;
said power cord being positioned in said case, said power cord being positioned in said case with said second end extending through a respective one of said pair of holes;
said power cable being positioned in said case, said power cable being positioned in said case with said second terminus extending through a respective one of said pair of holes; and
wherein said power cable and said power cord are positioned in said case with that said coupler and said connector are positioned outside of said case and extendable away from said case when the user withdraws said power cable and said power cord through said pair of holes, said coupler being configured to engage a respective said coupling end of said male pigtail or said female pigtail with said pair of wire contacts being configured to electronically couple to the equipment undergoing repair, such that supplying power to the equipment during diagnostic testing and repair can be performed in a safe and convenient manner.
